(19) United States
(12) Patent Application Publication
(10) Pub. No.: US 2018/0019335 A1
(43) Pub. Date: Jan. 18, 2018

(54) GRADED AND STEPPED EPITAXY FOR CONSTRUCTING POWER CIRCUITS AND DEVICES

(71) Applicant: Global Power Technologies Group, Inc., Lake Forest, CA (US)

(72) Inventor: Rahul Radhakrishnan, Lake Forest, CA (US)

(21) Appl. No.: 15/652,085

(22) Filed: Jul. 17, 2017

Related U.S. Application Data
(60) Provisional application No. 62/363,173, filed on Jul. 15, 2016.

(51) Int. Cl. H01L 29/78; H01L 29/267; H01L 29/04; H01L 29/66; H01L 21/04

(52) U.S. Cl. CPC H01L 29/7813; H01L 29/7842; H01L 29/66068; H01L 21/0445; H01L 29/045; H01L 29/267

(57) ABSTRACT

An exemplary doping profile for an epitaxial layer reduces the on-state resistance (R_{ON}) and off-state capacitance (C_{D}). A reduction in on-state resistance improves the forward voltage drop (V_{F}). Compared to constant epitaxial doping, non-uniform doping of the epitaxial layer can optimize trade-offs between on-state resistance (R_{ON}) and off-state capacitance (C_{D}), and off-state blocking of power devices. In some embodiments, the doping profile for the epitaxial layer may be graded or gradual. In some embodiments, the doping profile for the epitaxial layer may be a stepped or a stepwise function.

### CROSS REFERENCE TO RELATED APPLICATION

This patent application claims the benefit of U.S. Provisional Patent Application No. 62/363,173, filed Jul. 15, 2016, entitled “GRADED AND STEPPED EPITAXY TO IMPROVE PERFORMANCE OF UNIPOLAR VERTICAL SIC POWER DEVICES”. The entire content of the before-mentioned patent application is incorporated by reference as part of the disclosure of this application.

### TECHNICAL FIELD

This patent document relates to semiconductor circuits and technologies based on wide bandgap semiconductor materials such as silicon carbide (SiC) and other semiconductor materials.

### BACKGROUND

Semiconductor materials having wide bandgaps such as silicon carbide (SiC) semiconductor materials and others can exist in various crystalline forms and can be used to construct a range of circuits and devices. For example, in comparison with the commonly used silicon, SiC materials possess properties such as a wide bandgap structure and higher breakdown field. These properties make SiC materials attractive for a wide range of circuits and applications including high power electronics.

### SUMMARY

Techniques, systems, and devices are described for doping various regions of power circuits and devices, including circuits and devices based on SiC and GaN semiconductors and other semiconductors.

In an exemplary embodiment, a semiconductor device is disclosed. A semiconductor device comprises a doped substrate, a buffer layer, and an epitaxial layer. The buffer layer is formed over the doped substrate. The buffer layer is doped to exhibit a buffer doping profile. The epitaxial layer is formed over the buffer layer. The epitaxial layer is doped to exhibit a spatially varying epitaxial doping profile.

In an exemplary embodiment, another semiconductor device is disclosed. The semiconductor device comprises a substrate and an epitaxial layer formed over the substrate, where the epitaxial layer is doped according to an epitaxial doping profile.

### BRIEF DESCRIPTION OF THE DRAWINGS

FIG. 1A shows a semiconductor device for an exemplary doped epitaxial layer.

FIG. 1B shows a semiconductor device for another exemplary doped epitaxial layer.

FIG. 2 shows a semiconductor device for another exemplary doped epitaxial layer.

FIG. 3 shows several exemplary epitaxial layer doping schemes.

FIGS. 4A and 4B show exemplary doping and thickness for various two-step and three-step epitaxies, respectively, in comparison with standard constant-doped epitaxy.

FIG. 5 shows doping profile for a three-step epitaxy measured in secondary ion mass spectrometry (SIMS) versus growth target.

FIG. 6 shows exemplary capacitance and thickness for a one-step and three-step epitaxies at various blocking voltages of the semiconductor device.

FIGS. 7A, 7B and 8 illustrate diode and field-effect transistor examples based on the disclosed graded or stepped structures.

### DETAILED DESCRIPTION

Power circuits and devices can be designed and constructed to have certain properties in meeting application requirements. For instance, power circuits and devices may be constructed to exhibit a low resistance in the on-state (R_{ON}), a high resistance in the off-state, a low off-state capacitance, or a fast switching speed when switching between the on state and the off state. Semiconductors with large bandgaps, such as Silicon Carbide (SiC), may be used as alternatives to Silicon (Si) for forming power circuits and devices in many applications by offering a better trade-off in configuring these device parameters.

Power devices can be fabricated with an epitaxial drift region of constant doping. Non-uniform doping of this drift region can be used to optimize the trade-off between on-resistance and off-state blocking of a unipolar power device. A doping profile of epitaxial doping monotonically increasing away from the junction modeled as a particular infinite power series allows 11.5% reduction in cost through die-shrink. Such a non-uniform doping profile may be represented in Equation (1) below,

$${N}_{d} ( x ) = \frac{ε {E}_{c}^{2}}{3 {qV}_{B} \sqrt{1 - 2 {E}_{c} x / 3 {V}_{B}}} \qquad Eq . ( 1 )$$

where N_{d}(x) is doping as a function of distance x from the semiconductor junction, E_{C} is the critical electric field, V_{B} is the blocking voltage, ε permittivity and q the electron charge.

One of the assumptions in arriving at Eq. (1) is that E_{C} and bulk electron mobility are independent of doping. This assumption may introduce significant errors in modeling SiC or Gallium Nitride (GaN) power devices. Studies have empirically shown a wide variation of SiC breakdown and bulk mobility with doping. Accordingly, while an optimum graded epitaxy exists for SiC, the doping function can be different from Eq. (1).

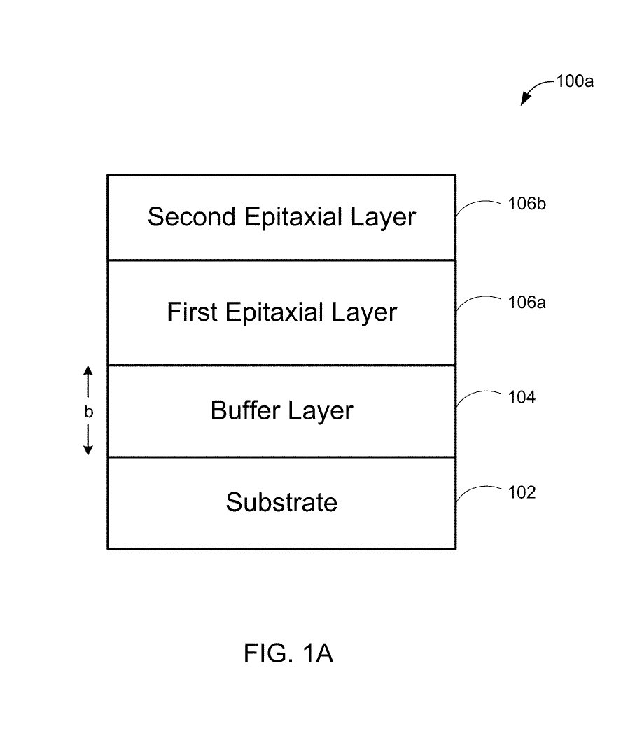

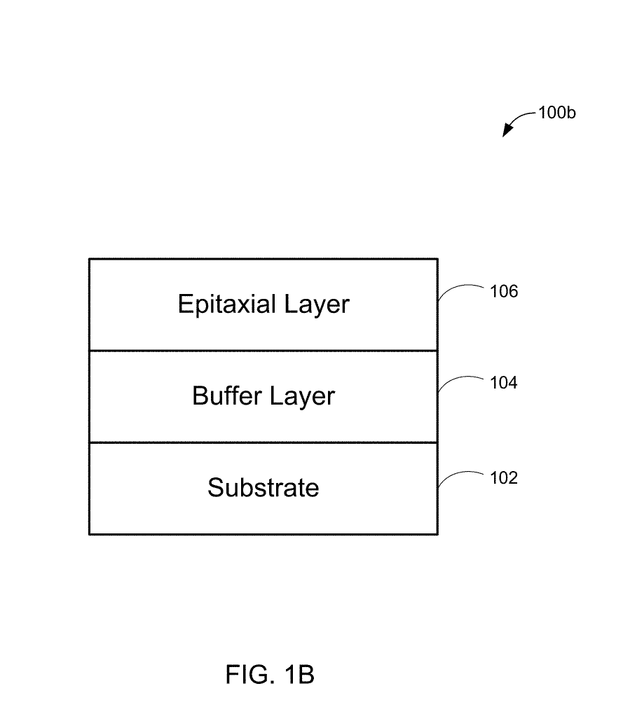

FIG. 1A shows an example of a semiconductor device 100a including a graded or gradually doped epitaxial layer 106a formed over a wide bandgap substrate 102. In implementations, the wide bandgap substrate 102 may be highly doped, and the buffer layer 104 is formed over the doped substrate 102. The doping of the doped buffer layer 104 is reduced monotonically as the buffer layer 104 is grown over the doped substrate.

The disclosed technology allows growth of the graded buffer layer 104 on the substrate 102, and the first epitaxial layer 106a formed over the graded buffer layer 104. A second epitaxial layer 106b can be further grown over the first epitaxial layer 106a. In some implementations, additional epitaxial layers can be formed over the second epitaxial layer 106b. Each of additional epitaxial layers may be formed with a doping lower than the previous epitaxial layer. The profile of buffer layer 104 doping can be optimized as a function of the distance x in the direction of growth from the doped substrate 102. The buffer layer 104 being of a desired thickness and with doping varying monotonically between epitaxial doping at the epi-buffer interface and substrate doping at the substrate-buffer interface. In an implementation, the doping of the epitaxial layer is lower than the substrate doping, and the doping of the buffer layer 104 decreases monotonically from the substrate-buffer interface to the epitaxial-buffer interface. The thickness of the buffer layer 104 and function of buffer layer doping are designed to maximize the conductivity of the device in the on-state while maintaining the off-state blocking voltage at a desired level. In addition, the buffer layer design may minimize the specific depletion capacitance of the semiconductor junction. One benefit of a reduced specific depletion capacitance is that a semiconductor device can switch between blocking and conducting states faster. This property benefits wide bandgap semiconductor devices, such as SiC and GaN, more than silicon devices because the former may operate at higher frequencies, and may have to switch between blocking and conducting states more often in a given time period. Thus, power loss due to switching may be a larger proportion in the wide bandgap semiconductor devices than power loss while in the blocking or conducting states. Thus, improving the specific depletion capacitance may reduce power switching loss which may reduce total energy loss in wide bandgap devices.

In some embodiments, the thickness of the buffer layer 104 may be lower than that of both the epitaxial layer and the substrate. Substrate thickness may vary from approximately 100 μm to 350 μm. The combined thickness of all epitaxial layers, including a single epitaxial layer, could vary from approximately 5 μm to 100 μm. The buffer layer may be approximately 0.5 μm to 2 μm. In some embodiments, the buffer layer 104 may be doped uniformly and sufficiently high to terminate reverse electric field within the buffer layer 104. The buffer layer 104 may have a lower doping concentration than the doping of the substrate.

The thickness of buffer layer 104 (“b”) such that a function of b may equal N, the doping of the first epitaxial layer 106a. The thickness of the first epitaxial layer 106a can be equal to the thickness “b” of the buffer layer 104. In some implementations, the first epitaxial layer may be doped less than the buffer layer, and the doping profile of the first epitaxial layer may monotonically decrease away from buffer layer. The rest of the epitaxial layer or the second epitaxial layer 106b may be grown at uniform doping. The first epitaxial layer 106a may have a smaller doping concentration than the doping of the buffer region to support reverse voltage in the epitaxial layer.

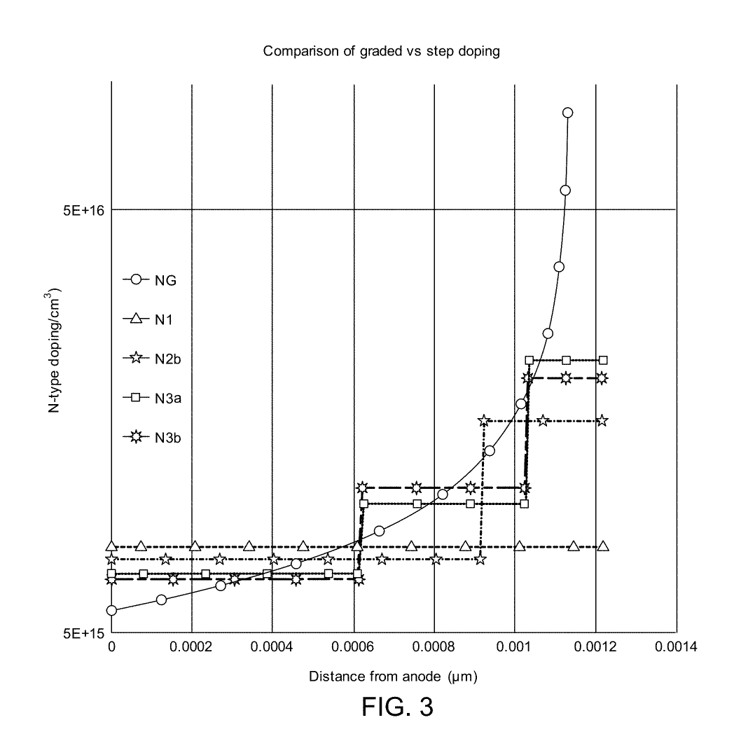

FIG. 1B shows an example of a semiconductor device 100b where the entire epitaxial layer 106 can be graded doped along a monotonic profile. An example of the graded doped epitaxial layer is shown as a curve titled NG in FIG. 3. Curve NG in FIG. 3 rotated ninety degree clockwise shows the graded doped profile of the epitaxial layer 106 of FIG. 1B so that the graded doped profile of the epitaxial layer monotonically decreases away from the buffer layer. In FIG. 1B, the substrate 102 and the buffer layers 104 may be doped as described above with respect to FIG. 1A. The epitaxial layer 106 may have a smaller doping concentration than the doping of the buffer region to support reverse voltage in the epitaxial layer. A benefit of graded doped epitaxial layer, labeled as NG in FIG. 3, is that it may achieve the most reduction in drift resistance (R_{DRIFT}) at the same voltage. The on-resistance (R_{ON}) includes the drift resistance (R_{DRIFT}) and additional resistance components, such as the resistance from the substrate. Accordingly, a reduction in drift resistance (R_{DRIFT}) results in a reduction in the on-resistance (R_{ON}). In addition, the graded doped epitaxial layer may achieve reduction in depletion capacitance (C_{D}) at the same voltage.

In an implementation, the doping of an epitaxial layer or the buffer is reduced by varying the dopant concentration in the epitaxial reactor as a function of time during the growth process. If the concentration of the dopant-containing gas is varied as a function of time, the concentration of the dopant as a function of distance from the substrate surface can be varied.

In some embodiments, a Silicon Carbide unipolar device may be manufactured with a substrate, buffer layer and epitaxial layer as shown in FIGS. 1A and 1B. The operation of a unipolar device depends on the doping concentration density of only one type of carrier, either n-type or p-type. An example of a SiC unipolar diode may include a Junction Barrier Schottky (JBS) diode. The JBS diode has a different trade-off of forward and reverse performance compared to the traditional 1-D Schottky diode. Hence, the function of variation of buffer and epitaxial layer doping is different for SiC JBS diodes compared to 1-D diodes or transistors. The SiC device edge termination is sensitive to lithography dimensions. If the epitaxial doping at the edge-termination is higher, the magnitude of lithographic dimensions required in the edge termination is lower and sensitivity to variation of dimensions is higher, both of which increases process complexity. Using the disclosed graded or stepped epitaxy allows for lower epitaxial doping at the surface of the device compared to standard constant doped epitaxy and hence wider termination region dimensions that are less sensitive to lithographic variations. The disclosed graded growth of SiC epitaxial layers can be applicable to various SiC unipolar devices or SiC vertical power devices that also have a nearly 1-dimensional field profile, including, for example, Schottky diode, PIN diode, JBS diode, vertical JFETs, and vertical MOSFETs, such as DMOSFETs or trench MOSFETs. One benefit of the vertical structure is that the current rating of the device is proportional to its area and the voltage blocking capability is achieved in the thickness of the die. With this structure, one of the connections of the transistor device may be located on the bottom of the semiconductor die.

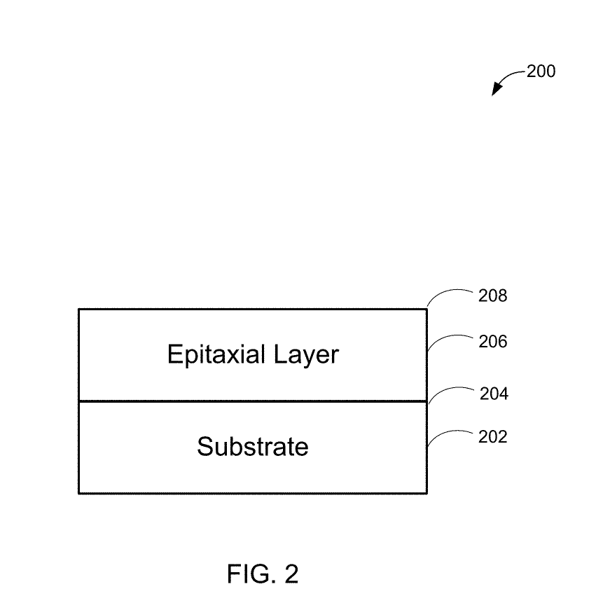

FIG. 2 shows another semiconductor device 200 with exemplary graded epitaxial layer. In this embodiment, the buffer layer and epitaxial layer may merge into each other. A Silicon Carbide unipolar device can be designed to exhibit an epitaxial doping increasing monotonically away from the blocking junction 208, such as for a Schottky junction, or decreasing monotonically away from the substrate 202. A blocking junction may include, for example, a p-n junction of a diode, a bipolar transistor, or a junction in a metal-oxide-semiconductor field-effect transistor (MOSFET) or a junction gate FET (JFET). As the distance from the blocking junction 208 increases, the rate of doping may also increase. In some implementations, the doping of a region of the epitaxial layer at or near the substrate-epitaxy interface 204 can be less than or equal to the doping of a region of the substrate at or near the substrate-epitaxy interface 204. A benefit of having the substrate and epitaxial layer of equal doping at or near the substrate-epitaxy interface is that it can further reduce the on-state resistance R_{ON}. In some embodiments, there may be a P-N junction at the top of the epitaxial layer 206 in which case there may be a shallow region of doping opposite to that of epitaxial doping at the top of the epitaxial layer 206. In such embodiments, the blocking junction 208 may be between the shallow region of opposite doping and the epitaxial layer 206.

In some embodiments, a Silicon Carbide unipolar device can be designed to exhibit epitaxial doping in a stepped fashion. Instead of monotonically increasing or decreasing doping, doping varies along a direction in steps, e.g., each step being higher doped than the one before but having constant doping within that step. For example, the epitaxial layer 206 of FIG. 2 can be doped in a stepwise manner increasing away from the blocking junction of the device or decreasing away from the substrate-epitaxy interface 204. In another example, the epitaxial layer 106a of FIG. 1A or 106 of FIG. 1B can be can be doped in a stepwise manner decreasing away from the buffer layer 104.

A benefit of a SiC device with a stepped epitaxial doping is that it can reduce the resistance of the drift region (R_{DRIFT}) below that achieved by an epitaxial layer with a constant doping. For example, in some embodiments, the drift resistance of a SiC device with a stepped epitaxial doping can be reduced by 7.34% compared to a drift resistance of a SiC device with a constant epitaxial doping. Another benefit of a SiC device with a stepped epitaxial doping is that, in some embodiments, it can permit shrinkage of approximately 3% of the die in typical commercial devices between 600 V and 1700 V while keeping the same electrical characteristics. At higher blocking voltage, for example, 10 kV, R_{DRIFT} may be predominant in R_{ON}, and the shrink level will increase asymptotically to 7.34%.

FIG. 3 shows various epitaxial layer doping schemes, such as constant doped (N1), graded doped (NG), two-stepped doping (N2b) and two schemes of three-stepped doping (N3a and N3b). The x-axis represents distance from the anode in μm and the y-axis represents the type of doping in/cm³. FIG. 3 shows the epitaxial doping increasing in a stepwise fashion away from the anode and towards the substrate or buffer in the graphs referred to as N2b, and N3a and N3b, which are two-step and three-step epitaxies, respectively. The graph for the graded doping (NG), which may follow Equation (1), also shows a gradual increase in the doping away from the anode and towards the substrate or buffer.

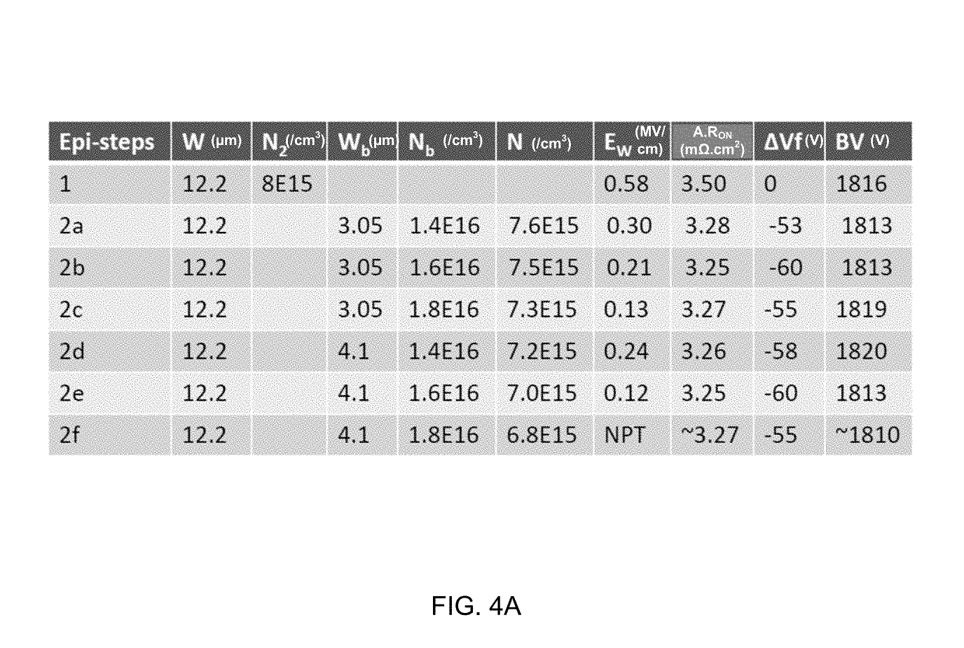

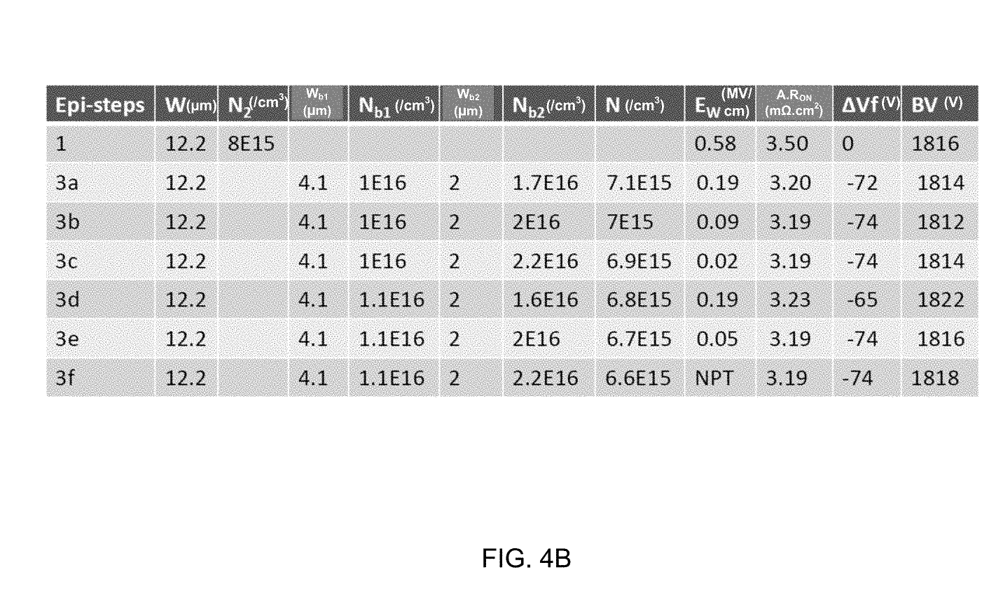

The exemplary doping and thickness for two-step and three-step epitaxies are shown in FIGS. 4A and 4B, respectively. The Epi-Steps shown in FIGS. 4A and 4B refers to different configurations for the two-stepped doping and three-stepped doping, respectively. The reduction in on resistance (R_{ON}) and forward voltage for two-step epitaxy is shown in FIG. 4A. The reduction in R_{ON} is shown as the reduction in on-state voltage drop in the column title ΔV_{f}. FIGS. 4A and 4B show that the 2-step and 3-step epitaxy options show reduction the on-state voltage drop compared to the 1-step or constant doping option while keeping blocking voltage (BV) the same.

The top layer doping of the two-step epitaxy, N, can be determined using Equation (2):

$$N = \frac{( {N}_{2} {W}^{2} - {N}_{b} {W}_{b}^{2} )}{( {W}_{2} - {W}_{b}^{2} )} \qquad Eq . ( 2 )$$

where N₂ is the equivalent one-step or constant doping, N_{b} is the bottom layer doping of the two-step, W_{b} is the bottom layer thickness of the two step, and W is the total thickness of the one and two step epitaxy. In an exemplary embodiment, Epi-step 2b may be chosen so that the width W_{b} of the bottom layer may be 3.05 μm with a doping N_{b} of 1.6×10¹⁶/cm³, and the width of the top layer may be 9.65 μm with a doping N of 7.5×10¹⁵/cm³.

FIG. 4B shows reduction in on resistance (R_{ON}) and forward voltage for three-step epitaxy. The top layer doping of the three-step epitaxy, N, can be determined using Equation (3):

$$N = \frac{{N}_{2} {W}^{2} - {N}_{b 1} \{ {( {W}_{b 1} + {W}_{b 2} )}^{2} - {W}_{b 2}^{2} \} - {N}_{b 2} {W}_{b 2}^{2}}{{W}^{2} - {( {W}_{b 1} + {W}_{b 2} )}^{2}} \qquad Eq . ( 3 )$$

where N₂ is the equivalent one step doping, N_{b1} is the middle layer doping, and N_{b2} is the bottom layers doping, W_{b1} and W_{b2} are the middle and bottom layer thickness corresponding to N_{b1} and N_{b2}, respectively, and W is the total thickness of the constant doped and three-step doped epitaxies. In an exemplary embodiment, epitaxy option 3b may be chosen so that the width W_{b1} of the bottom layer may be 4.1 μm with a doping N_{b1} of 1×10¹⁶/cm³, the width W_{b2} of the bottom layer may be 2 μm with a doping N_{b2} of 2×10¹⁶/cm³, and the width of the top layer may be 6.1 μm with a doping N of 7×10¹⁵. In another exemplary embodiment, epitaxy option 3e may be chosen so that the width W_{b1} of the bottom layer may be 4.1 μm with a doping N_{b1} of 1×10¹⁶/cm³, the width W_{b2} of the bottom layer may be 2 μm with a doping N_{b2} of 2×10¹⁶/cm³, and the width of the top layer may be 6.1 μm with a doping N of 6.7×1015/cm³. This would mean total thickness of 12.2 μm for each of the three-step epitaxy options 3b and 3e, which coincides with the thickness of the constant-doped epitaxy. In this embodiment, both the three-stepped epitaxy options 3b and 3e reduce the on-state voltage drop by 74 mV compared to the constant-doped epitaxy, while maintaining the same blocking voltage. While one of the two-stepped epitaxy option in FIG. 4a reduced V_{f} by 53 mV, one of the three-step epitaxy option reduced V_{f} by 74 mV. Epitaxy options with larger number of steps can reduce V_{f} more, but the marginal reduction in V_{f} with increasing number of steps (n) of epitaxy may reduce so that after a certain n, the increased complexity of stepping epitaxy may be most costly than the reduction in V_{f} achieved. Thus, an epitaxial doping profile may decrease away from the buffer in a stepwise function according to a number steps, such as two or more steps, where each step includes a constant doping within that step.

When the number of steps increases, the epitaxial design and advantage in characteristics will increase and tend towards the graded epitaxy. While increasing the number of steps reduces the resistivity of the SiC device in the ideal case, reducing the number of steps increases accuracy and precision of the epitaxy grown and improves uniformity.

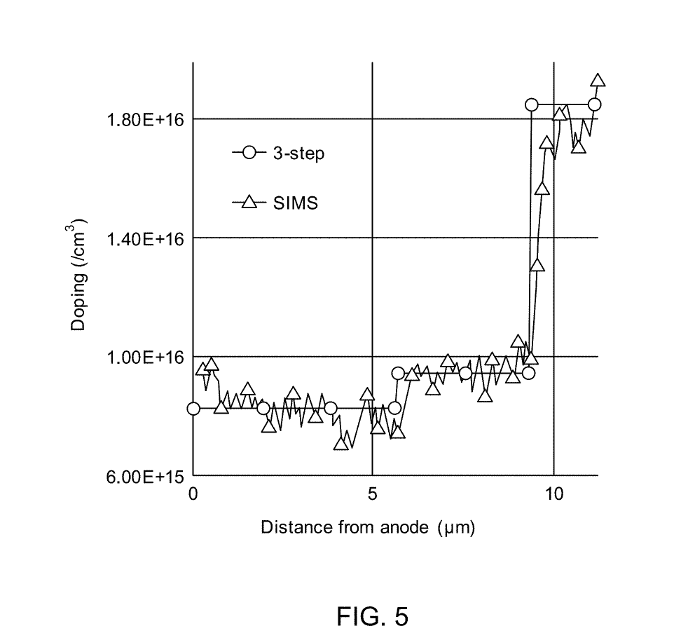

FIG. 5 shows doping profile measured by using secondary ion mass spectrometry (SIMS) versus growth target with approximately 10% doping variation between the two. Compared to the constant doped device, three-step epitaxy may require epitaxial growth to deal with sharp gradients in doping. A continuously graded epitaxy could make this gradient control more difficult since gradient may be present throughout the epitaxy rather than only at the steps, which might cause higher impact on doping uniformity. SIMS also shows more significant noise in the 3-step epitaxy than the constant doped epitaxy, especially at lower doping levels. However, noise from an epitaxial growth is expected to reduce once the growth process is stabilized through repetition.

Table 1 shows that three-step epitaxy exhibiting the same blocking performance (breakdown voltage and leakage current) as regular epitaxy while showing improved forward voltage drop (V_{F}); translating to improvement in R_{DRIFT} of 7.34% at room temperature and 5.47% at 175 C. The reverse leakage current and breakdown voltage are unchanged between the two cases, because peak electric field is designed not to change. Results in table-1 show that improvement in R_{DRIFT} is a function of temperature, and reduces from 7.34% at room temperature to 5.47% at 175 C.

TABLE 1
Device improvement with doping engineering

| | Constant | | Stepped | | Δ |
|---|---|---|---|---|---|
| V_{F,RT} | 1.53 | V | 1.50 | V | −20.8 mV |
| R_{Drift,RT} | 18.87 | mΩ | 17.48 | mΩ | −7.34% |
| V_{F,175C} | 2.10 | V | 2.06 | V | −43.5 mV |
| R_{Drift,175C} | 53.08 | mΩ | 50.13 | mΩ | −5.47% |
| I_{R,RT} | ~5 | μA | ~5 | μA | — |
| I_{R,175C} | ~150 | μA | ~150 | μA | — |
| BV | ~1615 | V | ~1615 | V | — |

Table 2 shows the calculated improvement in V_{F} and R_{DRIFT} at 175 C for 600V, 1200V and 1700V JBS diodes. As voltage rating increases, the proportion of R_{DRIFT} to R_{ON} increases. The resistance R_{ON} includes R_{DRIFT} with other resistance components such as resistance from the substrate. Improvement in R_{ON} will hence increase with voltage rating and tend to 7.34%. 600V devices show additional R_{ON} improvement since Schottky diodes are superior at 600 V, and they have higher R_{Drift}/R_{ON}. Reduction in R_{ON} translates to reduction in area of the device for the same static I-V parameters, under the assumption that increased current density doesn't significantly change junction temperature during operation. Reduction in die-size will be smaller than that reduction in active area because the overhead area of device termination is fixed. At higher voltage ratings, termination area overhead is higher, thus reducing die area savings further. Savings in die area are the highest for high current devices where most of die area is active area. Approximately 3% reduction in die-size can be achieved in commercial SiC JBS diodes in the 600 V-1700 V range by engineering the epitaxy as shown here. At higher voltage and current ratings, as R_{DRIFT}/R_{ON} ratio increases, reduction in R_{ON} and die-size will rise with current and blocking voltage to asymptotically reach the reduction in specific R_{DRIFT}, for example, 7.34%. ΔDie is smaller than ΔActive because die area is a sum of active area and termination area.

TABLE 2
Die shrink at different voltages

| | ΔV_{F,175C} | ΔR_{On.Sp,175C} | ΔActive | ΔDie |
|---|---|---|---|---|
| 600 V | −21 mV | −3.3% | −3.3% | −2.8% |
| 1200 V | −30 mV | −2.7% | −2.7% | −2.2% |
| 1700 V | −52 mV | −3.7% | −3.7% | −2.8% |

The disclosed technology can be applied to various wide bandgap semiconductors used to form vertical devices, for example, among others, SiC and Gallium Nitride (GaN).

The disclosed technology for the doping and thickness of the epitaxial layer in the exemplary vertical power devices can be used to achieve optimized electrical characteristics. For example, a vertical diode structure may have an optimum doping profile and thickness of the epitaxial layer to obtain the minimum drift resistance (R_{DRIFT}) and/or minimum depletion capacitance at a constant reverse voltage. In addition, for the same graded or stepped epitaxy, different performance improvements will be achieved in different vertical power devices. For example, in a JBS diode, stepped epitaxy that lowers the doping near the anode has the added advantage of improving JBS shielding and helping lower off state leakage current. For this reason, the graded epitaxy design has to be separately optimized for each unipolar SiC device.

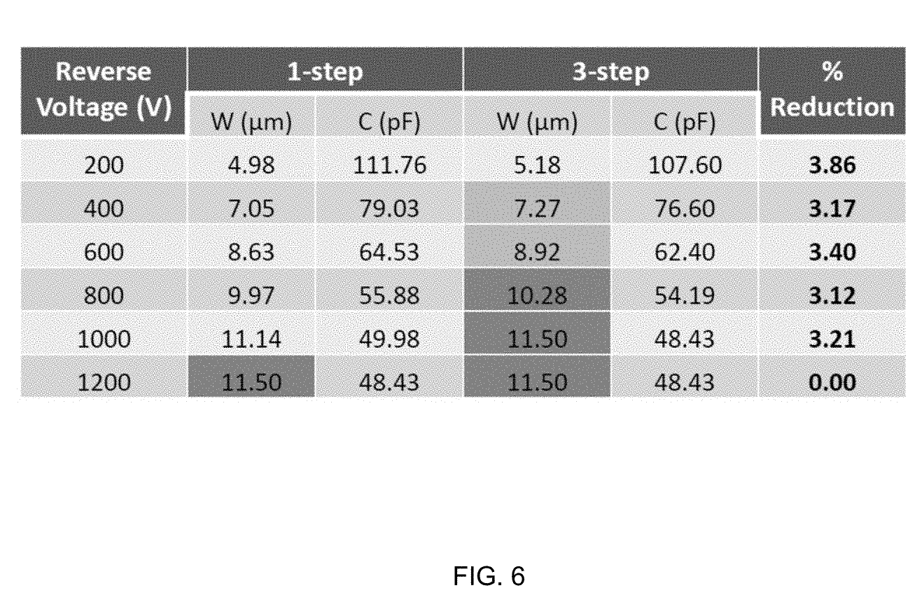

In addition to optimizing and reducing the on-state resistance of the device, the same scheme also reduces the off-state or depletion capacitance of the device. For the same graded or stepped epitaxy, different performance improvements will be achieved for on-resistance and off-capacitance. For example, one version of the graded or stepped epitaxy, such as shown in FIGS. 4A-4B, may minimize the on-state resistance but another version of the graded or stepped epitaxy, such as shown in FIG. 6, may minimize off-state capacitance. In embodiments where capacitance reduction is of higher value than resistance reduction, the version of graded or stepped epitaxy can be used, such as shown in FIG. 6.

FIG. 3 shows that doping near the junction is lower than the constant epitaxy with equivalent blocking performance. In reverse bias, lower doping leads to higher depletion width, and hence lower capacitance, at the same reverse voltage. The proportion of reduction in capacitance achieved is a function of the reverse voltage. At low blocking voltages, the epitaxy close to the junction is depleted, and hence the depletion capacitance in the off-state arises only from this region where the multi-step epitaxy is lower doped than the constant-doped epitaxy. At higher blocking voltages, depletion extends further into the epitaxy where multi-step epitaxy is not lower doped than constant-doped epitaxy, hence giving a lower reduction in capacitance in multi-step epitaxy compared to constant-doped epitaxy. Reduction in switching loss due to reduced capacitance is, hence a function of reverse voltage as well as the design of graded epitaxy.

FIG. 6 shows an exemplary capacitance and thickness for one-step and three-step epitaxies at different blocking voltages. As shown, graded epitaxy may lower specific capacitance by approximately 3%-4%. At 400V and 600V, the first epitaxial layer is punched through for 7.27 μm and 8.92 μm widths, respectively. In some implementations, the first epitaxial layer is the first from the junction and last from the substrate. At 800V, the second epitaxial layer is punched through for 8.92 μm width. In some implementations, the second epitaxial layer is the second from the junction and second from the substrate. At 1000V, the epitaxial layer is completely punched through for 11.5 μm width for three-step epitaxy. At 1200V, the epitaxial layer is completely punched through for 11.5 μm width for constant-doped and three-step epitaxies.

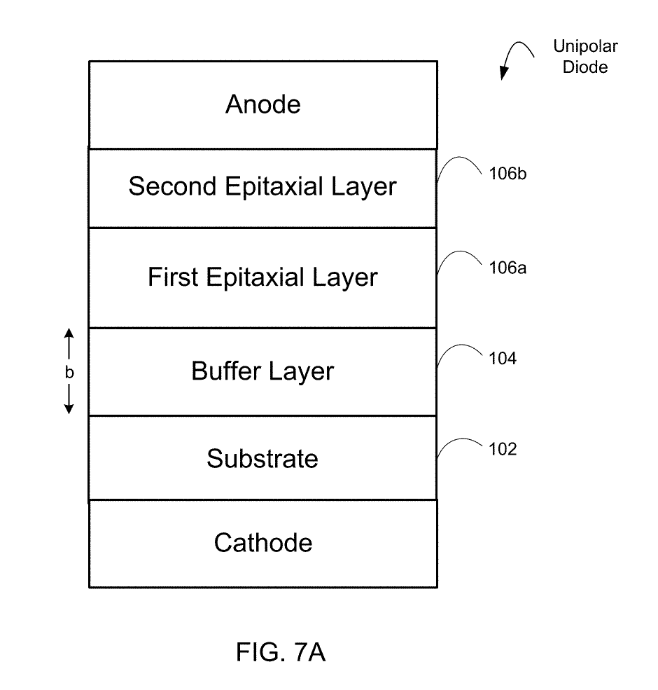

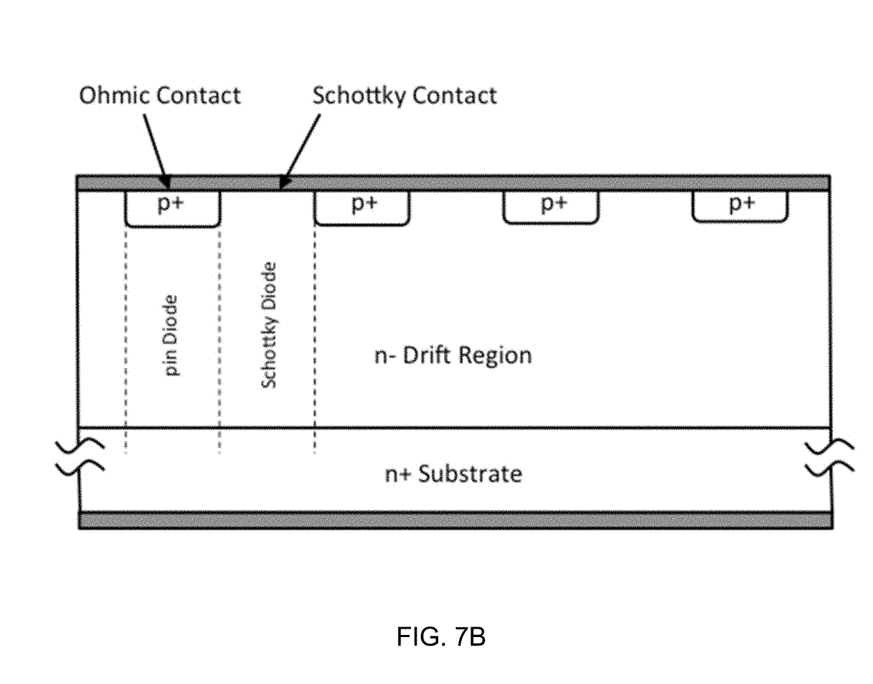

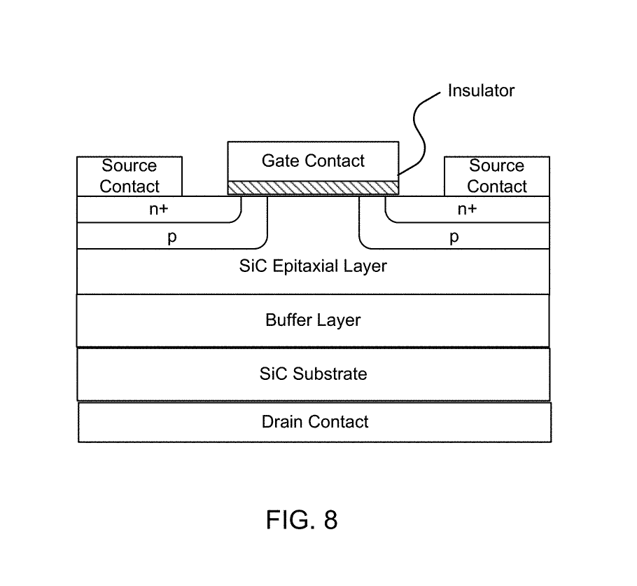

FIGS. 7A, 7B and 8 illustrate diode and field-effect transistor examples based on the disclosed graded or stepped structures.

FIGS. 7A and 7B show diode and junction barrier semiconductor (JBS) diode devices using the disclosed graded or stepped structures. Such a JBS diode device can be used to achieve a fast response and a low switching loss to increase the operation efficiency in applications, such as high-speed power switching systems. The JBS diode example in FIG. 7B includes interspersed Schottky and pin diodes, with the p+ regions spaced closely enough that they screen the Schottky regions from high electric fields in the blocking state. The design is a balance between the desire for low voltage drop in the forward direction and low leakage current in the reverse direction. In the on-state the Schottky contacts conduct at low forward voltage, and majority carrier electrons flow from the n− semiconductor into the Schottky metal. This constitutes the forward current, and the p+ regions do not inject minority carriers (holes) into the n− drift region unless a very high forward bias is applied. With no minority carriers to extract from the drift region, the turn-off is fast and the turn-off energy is low. In the blocking state, a depletion region extends from the Schottky contacts and p+ regions into the n− drift region. The electric field is approximately triangular with depth into the semiconductor, peaking at the upper surface. With proper design, the grounded p+ regions terminate the majority of the field lines at the upper surface, shielding the Schottky contacts from the highest electric field. The p+ regions shield the Schottky contacts from high electric fields in the blocking state.

FIG. 8 shows a silicon carbide metal insulator semiconductor field effect transistor (MISFET) device based on the disclosed graded or stepped structures over a SiC substrate. This example includes a first electrical contact formed on a first surface of the SiC substrate as one terminal of the MISFET device, a gate contact formed over the layer of the insulator material as a second terminal of the MISFET device and a second electrical contact as a third terminal of the MISFET device.

While this patent document contains many specifics, these should not be construed as limitations on the scope of any invention or of what may be claimed, but rather as descriptions of features that may be specific to particular embodiments of particular inventions. Certain features that are described in this patent document in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Moreover, the separation of various system components in the embodiments described in this patent document should not be understood as requiring such separation in all embodiments.

Only a few implementations and examples are described and other implementations, enhancements and variations can be made based on what is described and illustrated in this patent document.

What is claimed are techniques and structures as described and shown, including:

1. A semiconductor device, comprising:
a doped substrate;
a buffer layer formed over the doped substrate, wherein the buffer layer is doped to exhibit a buffer doping profile; and
an epitaxial layer formed over the buffer layer, wherein the epitaxial layer is doped to exhibit a spatially varying epitaxial doping profile.

2. The semiconductor device of claim 1, wherein the buffer doping profile monotonically varies between the doped epitaxial layer at an epitaxial-buffer interface and the doped substrate at a substrate-buffer interface.

3. The semiconductor device of claim 2, wherein the monotonically varying buffer doping profile decreases from the substrate-buffer interface to the epitaxial-buffer interface.

4. The semiconductor device of claim 1, wherein the epitaxial layer with the spatially varying epitaxial doping profile includes:
a first doping section adjacent to the buffer layer, the first doping section doped according to a first epitaxial doping profile, and
a second doping section adjacent to the first doping section, the second doping section doped according to a second epitaxial doping profile.

5. The semiconductor device of claim 4, wherein the first epitaxial doping profile monotonically decreases away from the buffer layer.

6. The semiconductor device of claim 4, wherein the first epitaxial doping profile decreases away from the buffer in a stepwise function according to a number of steps, wherein each step includes a constant doping within that step.

7. The semiconductor device of claim 6, wherein the number of steps is two or more steps.

8. The semiconductor device of claim 4, wherein the second epitaxial doping profile is a uniform doping.

9. The semiconductor device of claim 1, wherein the epitaxial doping profile is a monotonically graded profile.

10. The semiconductor device of claim 1, wherein the doped substrate, the buffer layer, and the epitaxial layer comprises either Silicon Carbide (SiC) or Gallium Nitride (GaN).

11. A semiconductor device, comprising:
a substrate; and
an epitaxial layer formed over the substrate, wherein the epitaxial layer is doped according to an epitaxial doping profile.

12. The semiconductor device of claim 11, wherein the epitaxial doping profile decreases monotonically away from the substrate.

13. The semiconductor device of claim 12, wherein a rate of decrease of the doping away from the substrate decreases as a function of a distance from the substrate.

14. The semiconductor device of claim 12, wherein
the substrate is doped, and
the doping of a region of the epitaxial layer near an interface of the substrate and the epitaxial layer is less than or equal to the doping of a region of the substrate near the interface of the substrate and the epitaxial layer.

15. The semiconductor device of claim 11, wherein the epitaxial doping profile decreases away from the substrate in a stepwise function according to a number of steps, wherein each step includes a constant doping within that step.

16. The semiconductor device of claim 15, wherein the number of steps is two or more steps.

17. The semiconductor device of claim 11, wherein the substrate and the epitaxial layer comprises either Silicon Carbide (SiC) or Gallium Nitride (GaN).
